(19) United States
(12) Patent Application Publication
(10) Pub. No.: US 2022/0163894 A1
(43) Pub. Date: May 26, 2022

(54) SYSTEM AND METHOD FOR DOUBLE-SIDED DIGITAL LITHOGRAPHY OR EXPOSURE

(71) Applicant: Zhongshan Aiscent Technologies Co, Ltd., Zhongshan, Guangdong (CN)

(72) Inventors: Wenhui Mei, Zhongshan (CN); Xiaojun Wang, Zhongshan (CN); Pingqiang Liao, Zhongshan (CN); Weichong Du, Zhongshan (CN)

(21) Appl. No.: 17/425,726

(22) PCT Filed: Jan. 25, 2019
(86) PCT No.: PCT/CN2019/073193

§ 371 Date: Jul. 25, 2021

(51) Int. Cl. G03F 7/20; G03F 9/00

(52) U.S. Cl. CPC G03F 7/2032; G03F 7/2057; G03F 9/7088; G03F 7/70466

(57) ABSTRACT

A double-sided digital lithography or exposure system and method are provided. The system includes a first optical engine 110 for exposing a front side of a substrate 910, a second optical engine 120 for exposing the back side of the substrate 910, a control system 710 for generating a first exposure pattern and a second exposure pattern aligned on the front and back surfaces of the substrate 910 based on the position information of the first optical engine 110 and the second optical engine 120, and controlling the first optical engine 110 and the second optical engine 120 to expose the front and back surfaces of the substrate 910 with the first exposure pattern and the second exposure pattern.

### CROSS-REFERENCE TO RELATED APPLICATIONS

The application is a continuation application of International application of PCT/CN2019/073193 with an international filing date of Jan. 25, 2019, the entire contents of which are incorporated herein by reference.

### TECHNICAL FIELD

The present disclosure relates to field of digital lithography, and more specifically, to a system and method for double-sided digital lithography or exposure.

### BACKGROUND

The double-sided digital lithography or exposure system and method, may be well defined as, a system and method for exposing a corresponding pattern on a substrate coated with a photosensitive material, such as a printed circuit board, by directly controlling the light output of an optical path system through digital controlling.

The traditional double-sided exposure system usually adopts film (mask) transfer pattern to expose the double-sided printed circuit board. Before the exposure, the film to be transferred needs to be made first, then the film with two sides of the pattern is fixed on the upper and lower sides of the glasses respectively, and then the circuit board to be transferred is sandwiched between the upper and lower glasses. A UV light source is used for the exposure, and the circuit pattern is transferred to the circuit board to complete the double-sided exposure.

Digital lithography systems for single-sided exposure are currently available on the market. This has the advantage of reducing the use of the mask, but only one exposure can be conducted at a time. However, most printed circuit boards (PCBs) require a double-sided exposure, and the use of a single-sided digital lithography system not only requires at least two exposures on the first side and the second side, and after the exposure of the first side, the second side needs to be exposed by a flip operation. However, the flip operation also causes a problem that the double-side exposure pattern alignment needs to be performed after the flip. Therefore, the digital lithography or exposure system with single-sided exposure not only increases the exposure flow, but also requires high-precision dual-sides positioning, thus greatly reducing the production yield and the yield of the equipment. However, the double-sided digital lithography or exposure system and method do not require double-sided pattern alignment (double-sided positioning) and are compatible with conventional double-sided exposure equipment and other processes. Therefore, the digital double-sided lithography or exposure system and method for double-sided exposure has a wide development prospect, and how to use double-sided lithography or exposure system for double-sided exposure of substrate becomes an urgent problem to be solved.

### SUMMARY

A digital lithography or exposure system and method are provided in the disclosure, which can improve the alignment accuracy of exposure patterns on both upper and low sides of a substrate.

In a first aspect, a digital double-sided lithography or exposure system is provided. The system includes a first optical engine 110 for exposing a front surface of the substrate 910, a second optical engine 120 for exposing a back surface of the substrate 910 and a control system 710 for generating a first exposure pattern and a second exposure pattern according to the position information of the first optical engine 110 and the second optical engine 120. The generated first exposure pattern and the generated second exposure pattern are aligned on the front and back surfaces of the substrate 910. The control system 710 is further configured to control the first optical engine 110 and the second optical engine 120 to expose the front and back surfaces of the substrate 910 with the first exposure pattern and the second exposure pattern, respectively.

In the double-sided digital lithography or exposure system provided by the present disclosure, the exposure patterns generated by the front and back optical engines are not fixed, but can be adjusted according to the positions of the two optical engines to compensate for the offset of the two optical engines such that the first exposure pattern projected by the first optical engine onto the substrate is precisely aligned with the second exposure pattern projected by the second optical engine onto the substrate, realizing an accurate exposure of both sides of the substrate.

In one possible implementation of the first aspect, the system further includes a calibration system for obtaining the position information of the first optical engine 110 and the second optical engine 120.

In one possible implementation of the first aspect, the calibration system 610 includes a first imaging device 410 for acquiring the position information of a reference mark on the substrate 910. The control system 710 is configured to generate the first exposure pattern and the second exposure pattern according to a position offset of the first optical engine 110 relative to the reference mark and the position offset of the second optical engine 120 relative to the reference mark.

In one possible implementation of the first aspect, the calibration system 610 includes a first beam splitting device 210 and a second beam splitting device 220, and the first imaging device 410 and the second imaging device 420. The first beam splitting device 210 and the first imaging device 410 are provided at one side of the first optical engine 110. The second beam splitting device 220 and the second imaging device 420 are provided at one side of the second optical engine 120. The first imaging device 410 is configured to receive a first light beam passing through the first optical engine 110 and reflected by the first beam splitting device 210. The second imaging device 420 is configured to receive a second light beam passing through the second optical engine 120 and reflected by the second beam splitting device 220. The control system 710 is further configured to determine a position of the first light beam and a position of the second light beam as the position of the first optical engine 110 and the position of the second optical engine 120, respectively.

In one possible implementation of the first aspect, the control system 710 is further configured to, during an exposure of the substrate 910, control the position of the first optical engine 110 and the position of the second optical engine 120 to remain unchanged, or control a relative position of the first optical engine 110 and the second optical engine 120 to remain unchanged.

In one possible implementation of the first aspect, the optical axis of the first optical engine 110 and an optical axis of the second optical engine 120 are both perpendicular to the substrate 910.

In one possible implementation of the first aspect, the system includes a first optical engine array and a second optical engine array. The first optical engine array is configured to expose a front surface of the substrate 910. The second optical engine array is configured to expose a back surface of the substrate. The optical engines included in the first optical engine array and the second optical engine array are each arranged in an (M, N) array. The M and N are natural numbers. The first optical engine array includes the first optical engine 110, and the second optical engine array includes the second optical engine 120.

In one possible implementation of the first aspect, a normal direction of the substrate 910 is a horizontal direction, a vertical direction, or a direction inclined at an arbitrary angle.

In one possible implementation of the first aspect, a bearing plate of the substrate 910 includes two glass plates. The substrate 910 is provided between the two glass plates and is flattened by the two glass plates.

In one possible implementation of the first aspect, the bearing plate of the substrate 910 includes a glass plate and a clamping plate. The substrate 910 is disposed on the glass plate. The clamping plate is configured to fix the substrate to the glass plate.

In one possible implementation of the first aspect, the bearing plate of the substrate 910 includes four clamping plates. The substrate 910 is fixed by the four clamping plates. The four clamping plates are respectively clamped at different positions of the substrate 910, and the substrate 910 is pulled flat by pulling forces in different directions.

In one possible implementation of the first aspect, the substrate 910 is a flexible. The bearing flexible substrate 910 is a roller. The substrate 910 is fixed by a pair of rollers.

In one possible implementation of the first aspect, the exposure manners employed in the system include any one of an exposure method based on a digital micro-mirror DMD, a method based on a single laser scanning imaging, and a method based on a semiconductor laser fiber coupled laser.

In a second aspect, a digital double-sided digital lithography or exposure system is provided. The system includes a first optical engine 110 for exposing a front surface of the substrate 910, a second optical engine 120 for exposing a back surface of the substrate 910, a calibration system 610, configured to obtain a position information of the first optical engine 110 and the second optical engine 120 and a control system 710 for generating a first exposure pattern and a second exposure pattern according to the position information of the first optical engine 110 and the second optical engine 120. The generated first exposure pattern and the generated second exposure pattern are aligned on the front and back surfaces of the substrate 910.

The calibration system provided in the present disclosure can be used to calibrate a mounting position of an optical engine. After the calibration, all the optical engines can have a precise position definition in the system coordinates of the exposure. The control system can disassemble and align the exposure pattern according to the position of the engine, so as to realize accurate exposure of the pattern on both sides of the substrate.

In the digital double-sided lithography or exposure system provided by the present disclosure, the exposure patterns generated by the front and back optical engines are not fixed, but can be adjusted according to the positions of the two optical engines to compensate for the offset of the two optical engines such that the first exposure pattern projected by the first optical engine onto the substrate is precisely aligned with the second exposure pattern projected by the second optical engine onto the substrate, realizing an accurate exposure of both sides of the substrate.

In a third aspect, a method for double-sided digital lithography or exposure is provided. The method is applied to the digital double-sided lithography or exposure system of the first aspect or the second aspect. The method includes generating a first exposure pattern and a second exposure pattern based a position information of the first optical engine 110 and the second optical engine 120 and controlling the first optical engine 110 and the second optical engine 120 to expose the front and back surfaces of the substrate 910 with the generated first exposure pattern and the generated second exposure pattern, respectively. The generated first exposure pattern and the generated second exposure pattern are aligned on the front and back surfaces of the substrate 910.

In one possible implementation of the third aspect, the method further includes acquiring the position information of the first optical engine 110 and the second optical engine 120.

In one possible implementation of the third aspect, the method further includes acquiring a position information of reference marks on the substrate 910. The step of generating the first exposure pattern and the second exposure pattern based on the position information of the first optical engine 110 and the second optical engine 120 includes generating the first exposure pattern and the second exposure pattern based on a positional offset of the first optical engine 110 with respect to the reference marks and the positional offset of the second optical engine 120 with respect to the reference marks.

In one possible implementation of the third aspect, the step of obtaining the position information of the first optical engine 110 and the second optical engine 120 includes receiving a first light beam passing through the first optical engine 110 and reflected by the first beam splitting device 210, receiving a second light beam passing through the second optical engine 120 and reflected by a second beam splitting device 220 and determining a position of the first light beam and a position of the second light beam as the position of the first optical engine 110 and the position of the second optical engine 120 respectively.

In one possible implementation of the third aspect, the method further includes controlling the position of the first optical engine 110 and the position of the second optical engine 120 to remain unchanged during an exposure of the substrate 910; or controlling a relative position of the first optical engine 110 and the second optical engine 120 to remain unchanged.

In one possible implementation of the third aspect, the optical axis of the first optical engine 110 and the optical axis of the second optical engine 120 are both perpendicular to the substrate 910.

In a fourth aspect, a method for double-sided digital lithography or exposure is provided. The method is applied to the digital double-sided lithography or exposure system of any of the implementations of the second aspect or the second aspect described above. The method includes acquiring a position information of the first optical engine 110 and the second optical engine 120 and generating a first exposure pattern and a second exposure pattern according to the position information of the first optical engine 110 and the second optical engine 120. The first exposure pattern and the second exposure pattern are aligned on the front and back surfaces of the substrate 910.

In a fifth aspect, a computer-readable storage medium for storing a computer program is provided. The computer program contains instructions for executing the method of the third or fourth aspect described above or any of its possible implementations.

In a sixth aspect, a system chip including a processing unit and a communication unit is provided. The process unit is configured to execute computer instructions causing the chip to implement the method of the third or fourth aspect described above or any of the possible implementation thereof.

In a seventh aspect, computer program products including instructions for executing the method of the third or fourth aspect described above or any of the possible implementations thereof are provided.

### BRIEF DESCRIPTION OF DRAWINGS

FIG. 1 is a schematic structural diagram of a first digital double-sided lithography or exposure system provided by an embodiment of the present disclosure.

FIG. 2 is a schematic structural diagram of a second digital double-sided lithography or exposure system provided by an embodiment of the present disclosure.

FIG. 3 is a schematic structural diagram of a third digital double-sided lithography or exposure system provided by an embodiment of the present disclosure.

FIG. 4 is a schematic structural diagram of a fourth digital double-sided lithography or exposure system provided by an embodiment of the present disclosure.

FIG. 5 is a schematic structural diagram of a fifth digital double-sided lithography or exposure system provided by an embodiment of the present disclosure.

FIG. 6 is a schematic structural diagram of a first optical engines arrangement according to an embodiment of the present disclosure.

FIG. 7 is a schematic structural diagram of a second optical engines arrangement according to an embodiment of the present disclosure.

FIG. 8 is a schematic structural diagram of a third optical engines arrangement according to an embodiment of the present disclosure.

FIG. 9 is a schematic structural diagram of a fourth optical engines arrangement according to an embodiment of the present disclosure.

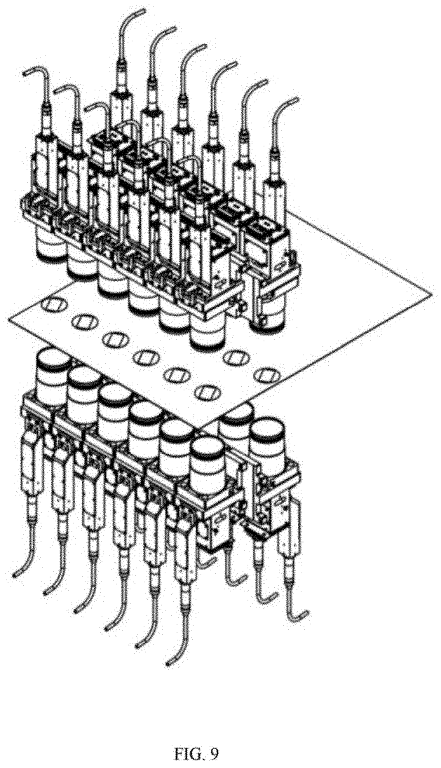

FIG. 10 is a schematic diagram of a stitching area formed after scanning by a digital double-sided lithography or exposure system according to an embodiment of the present application.

FIG. 11 is a schematic diagram of a stitching area formed after the entire scanning area of the digital double-sided lithography or exposure system is scanned and exposed by two rows of optical engines at one time.

FIG. 12 is a schematic configuration diagram of an arrangement position of a substrate according to an embodiment of the present disclosure.

FIG. 13 is a schematic structural diagram of a carrying mechanism according to an embodiment of the present disclosure.

FIG. 14 is a schematic structural diagram of a soft board roll-to-roll substrate feeding according to an embodiment of the present disclosure.

FIG. 15 is a schematic structural diagram of a digital lithography or exposure system based on DMD provided by an embodiment of the present disclosure.

FIG. 16 is a schematic structural diagram of a digital lithography or exposure system based on a single-beam laser scanning provided by an embodiment of the present disclosure.

FIG. 17 is a schematic structural diagram of a digital lithography system based on fiber-coupled close-spaced laser lattice imaging provided by an embodiment of the present disclosure.

FIG. 18 is a schematic diagram of an optical fiber provided in an embodiment of the present disclosure.

FIG. 19 is a schematic diagram of an optical fiber coupling and closely spaced laser lattice according to an embodiment of the present disclosure.

FIG. 20 is a schematic flow chart of a method for double-sided digital lithography or exposure provided by an embodiment of the present disclosure.

FIG. 21 is a schematic flow chart of another method for double-sided digital lithography or exposure provided by an embodiment of the present disclosure.

### DETAILED DESCRIPTION OF THE EMBODIMENTS

The technical solution in the present disclosure will be described below with reference to the accompanying drawings.

It should be understood that embodiments of the present application relate to digital lithography or direct-write digital imaging techniques, and in particular to digital double-sided lithography systems. The digital double-sided lithography system is also referred to as a digital double-sided exposure system or a double-sided maskless exposure system. The system is capable of simultaneously exposing two surfaces of a substrate, such as a substrate for a printed circuit board (PCB), or a die plate for a lead frame, etc. Embodiments of the present application can be applied to a double-sided exposure in the manufacture of the PCBs, integrated circuit (IC) packaging, and liquid crystal displays, and also to document printing, photocopying or the like.

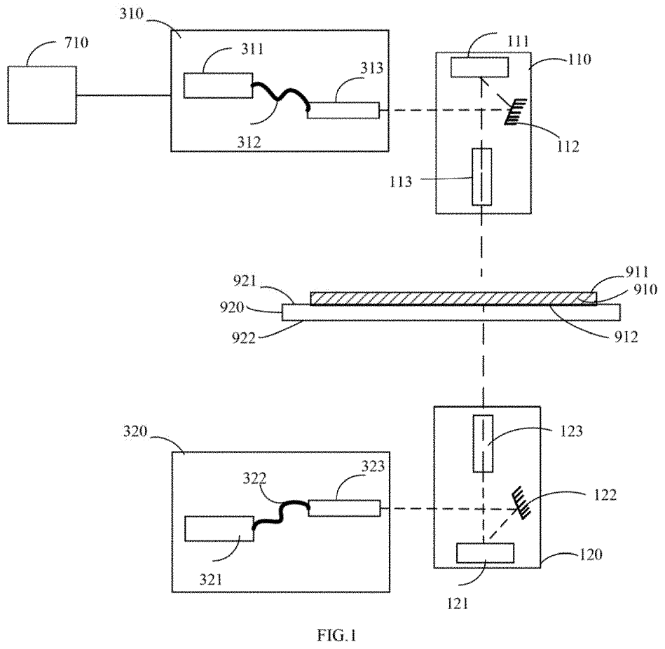

FIG. 1 is a schematic block diagram of a digital double-sided lithography or exposure system provided by an embodiment of the present disclosure. As shown in FIG. 1, the digital double-sided lithography or exposure system includes a first optical engine 110 and a second optical engine 120.

The first optical engine 110 and the second optical engine 120 are respectively provided on two sides of the substrate 910 for exposing the front and back sides of the substrate 910. For example, the first optical engine 110 may be used to expose a front surface of the substrate 910, and the second optical engine 120 may be used to expose a back surface of the substrate 910.

The first optical engine 110 is provided at a first side of the substrate 910. For example, as shown in FIG. 1, the first optical engine 110 is provided on a substrate 910 for generating a first exposure pattern and projecting the first exposure pattern onto a first surface 911 of the substrate 910. The exposure of the first side 911 of the substrate 910 is thus realized. A second optical engine 120 is provided on a second side of the substrate 911. For example, as shown in FIG. 1, the second optical engine 120 is provided under the substrate 910 for generating a second exposure pattern and projecting the second exposure pattern onto a second surface 912 of the substrate 910. The exposure of the second side 912 of the substrate 910 is thus realized.

In the technical solution provided by the embodiment of the present disclosure, the first optical engine 110 and the second optical engine 120 are respectively disposed on both sides of the substrate 910, instead of using one optical engine to respectively expose both sides of the substrate. The first optical engine 110 and the second optical engine 120 can simultaneously expose the front and back surfaces of the substrate 910, and the exposure processes can be simplified.

The digital double-sided lithography or exposure system may also include a control system 710 that may be configured to, based on the position information of the first optical engine 110 and the second optical engine 120, generate a first exposure pattern and a second exposure pattern. The generated first exposure pattern and the second exposure pattern are aligned on the front and back surfaces of the substrate 910.

The control system 710 is further configured to control the first optical engine 110 and the second optical engine 120 to expose the front and back surfaces of the substrate 910 with the first exposure pattern and the second exposure pattern, respectively.

In other words, the control system 710 may be operable to generate a first exposure pattern based on the position information of the first optical engine 110, and control the first optical engine 110 to expose the front surface of the substrate 910 with the generated first exposure pattern. The control system 710 may be further configured to generate a second exposure pattern according to the position information of the second optical engine 120, and control the second optical engine 120 to expose the back surface of the substrate 910 with the generated second exposure pattern.

Alternatively, the control system may be a computer device connected to the digital double-sided lithography or exposure system. The computer device is capable of controlling the system with software.

For example, if the control system determines that the optical center of the first optical engine 110 is offset by 1 mm in the X-axis relative to the optical center of the second optical engine 120, when the control system controls the optical engine to generate an exposure pattern, the first exposure pattern generated by the first optical engine 110 may be controlled to be offset by −1 mm in the X-axis relative to the second exposure pattern generated by the second optical engine 120. In this way, the adjusted first exposure pattern and the second exposure pattern can be precisely aligned on the front and back sides of the substrate 910.

Due to limited installation position accuracy of the optical engines, the first optical engine and the second optical engine cannot be completely aligned after installation, namely, the optical axes of the first optical engine and the second optical engine are not perfectly aligned. If the first optical engine and the second optical engine are used directly to expose the substrate, the exposure patterns of the upper and lower substrates cannot be aligned, and the exposure quality is affected. In relate arts, in order to realize accurate aligned exposures of the front and back surfaces of the substrate, a calibration mechanism is adopted to calibrate the optical axes of the first optical engine and the second optical engine. The optical axes of the first optical engine and the second optical engine are aligned, and the calibrated optical engines are used to realize accurate exposures of the substrate. This method requires the use of an additional mechanism to control the optical axis of the optical engine for alignment, which is complicated in operation and difficult to be implemented.

In the technical solution provided by the embodiment of the present disclosure, the process of aligning the optical axes of the first optical engine and the second optical engine can be omitted in the process of precisely exposing the front and back surfaces of the substrate. Data process is performed on the exposure patterns by the control system, and the exposure patterns of both the front and the back are generated by data conversion. The generated first exposure pattern and the second exposure pattern can compensate for the position offsets between the first optical engine and the second optical engine, realizing an accurate exposure of the front and back surfaces of the substrate, and simplifying the exposure process.

Furthermore, with reference to the prior patent (with an application No. 201210159451.0), the precise exposure of the upper and lower optical engines in this patent requires a complex alignment system by which the optical axes of the upper and lower optical engines are aligned, thus realizing an accurate exposure of the substrate. However, the digital double-sided lithography or exposure system according to the embodiments of the present disclosure can save the complicated alignment mechanism, and directly generate the aligned exposure pattern by means of software to realize the accurate exposure of the substrate. This approach can simplify the design of a double-sided lithography or exposure system and reduce costs.

The method for obtaining the positions of the first optical engine and the second optical engine by the control system 710 in the embodiment of the present disclosure is not specifically limited.

As one example, the positions of the first optical engine 110 and the second optical engine 120 are pre-stored in the control system 710. For example, since the positions of the first optical engine 110 and the second optical engine 120 are substantially fixed after the digitized double-sided lithography or exposure system leaves factory, and no change would occur.

Accordingly, the position information of the first optical engine 110 and the second optical engine 120 may be stored in the digitized double-sided lithography or exposure system upon the system leaves factory. The alignment of the generated exposure pattern may be performed directly using the position information during the exposure.

As another example, the first optical engine 110 and the second optical engine 120 may respectively expose an exposure pattern on the upper and lower sides of the substrate 910. For example, the first optical engine 110 exposes a pattern on the front side of the substrate while the second optical engine exposes a pattern on the back side of the substrate 910, and the offsets between the two optical engines can be determined by measuring the distance between the two exposure patterns. The control system may generate the first exposure pattern and the second exposure pattern based on the distances between the two exposure patterns, such as an offset distance between the two exposure patterns.

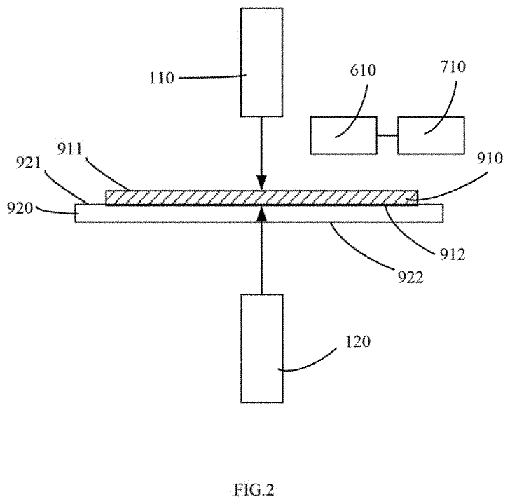

As yet another example, as shown in FIG. 2, the digitized double-sided lithography or exposure system may also include a calibration system 610 that may be used to, prior to the exposure, acquire the position information of the first optical engine 110 and the second optical engine 120, and send the position information of the first optical engine 110 and the second optical engine 120 to the control system 710. With the calibration system 610, the spatial positions or installation positions of the first optical engine 110 and the second optical engine 120 can be clearly calibrated.

Of course, the calibration system may also be an external component of the digital double-sided lithography or exposure system, rather than an essential component of the system.

For example, the calibration system may be a removable component, the calibration system being mounted on the system in case a calibration position is required before the exposure, and the calibration system can be disassembled after the calibration.

The process of aligning the exposure patterns by the calibration system 610 is described in detail below.

Before the first optical engine 110 and the second optical engine 120 expose the substrate 910, it is also necessary to align the exposure patterns of the first optical engine 110 and the second optical engine 120 on the upper and lower sides of the substrate 910 in order to ensure that alignment precision of the exposure patterns on the upper and low sides of the substrate 910.

Alignment of the exposure pattern may be achieved by a calibration system 610. The calibration system 610 can clearly calibrate the spatial position or installation position of the first optical engine 110 and the second optical engine 20. After the calibration, all of the optical engines may have a precise position definition in the system coordinates of the exposure for subsequent alignment of the exposure pattern.

The calibration system 610 may be used to obtain position information of the first optical engine 110 and the second optical engine 120. The calibration system 610 may also send the position information of the first optical engine 110 and the second optical engine 120 to the control system 710, so that the control system 710 generates a first exposure pattern and a second exposure pattern based on the position information of the first optical engine 110 and the second optical engine 120. The first exposure pattern and the second exposure pattern are aligned on both front and back sides of the substrate 910.

The control system 710 may control the position of the first exposure pattern generated by the first optical engine 110 to remain unchanged. By adjusting the position of the second exposure pattern generated by the second optical engine 120, the first exposure pattern and the second exposure pattern are aligned on both front and back sides of the substrate 910.

Alternatively, the control system 710 may control the position of the second exposure pattern generated by the second optical engine 120 to remain unchanged, by adjusting the position of the first exposure pattern generated by the first optical engine 110. The first exposure pattern and the second exposure pattern are aligned on both front and back sides of the substrate 910. Alternatively, the control system 710 may simultaneously control the position of the first exposure pattern generated by the first optical engine 110 and the position of the second exposure pattern generated by the second optical engine 120. The first exposure pattern and the second exposure pattern are aligned on both front and back sides of the substrate 910.

The position information of the first optical engine 110 and the second optical engine 120 may refer to spatial absolute position information of the first optical engine 110 and the second optical engine 120 and/or relative position information of the first optical engine 110 and the second optical engine 120. The relative position of the first optical engine 110 and the second optical engine 120 may refer to a positional offset of the first optical engine 110 with respect to the second optical engine 120.

In the technical solution provided by the embodiment of the present application, the exposure patterns generated by the optical engines of the front and back sides are not fixed, but can be adjusted according to the positions of the two optical engines to compensate for the offsets of the two optical engines. The first exposure pattern projected on the substrate by the first optical engine is precisely aligned with the second exposure pattern projected on the substrate by the second optical engine, so as to realize accurate exposure of both sides of the substrate. The calibration system may be used to align the exposure pattern before the optical engine exposes the substrate, the control system may control the optical engine to expose the substrate using the pattern after alignment in order to realize that accurate exposure of both sides of the substrate.

In the embodiment of the present disclosure, the manner in which the calibration system 610 obtains the position information of the first optical engine 110 and the second optical engine 120 is not specifically limited.

As one example, the calibration system 610 may include an imaging device operable to image an optical mark emitted by the first optical engine 110 and an optical mark emitted by the second optical engine 120 respectively to obtain the relative position information of the first optical engine 110 and the second optical engine 120. The optical mark may be, for example, a circular or cross pattern emitted by the optical engines.

As another example, the digital double-sided lithography or exposure system provided by embodiments of the present disclosure may also provide reference marks on the substrate 910. The calibration system 910 can obtain the position information of the optical mark emitted by the first optical engine 110 relative to the reference mark and the position information of the optical mark emitted by the second optical engine 120 relative to the reference mark. Since the position information of the optical mark emitted by the first optical engine and the optical mark emitted by the second optical engine are both relative to the same reference mark, the calibration system thus can obtain the position information of the first optical engine 110 relative to the second optical engine 120.

In the embodiment of the present disclosure, the setting modes of the reference marks are not specifically limited. For example, the reference marks may be some mark points provided on the substrate 910, or the reference marks may be some mark points provided on the carrying mechanism 920. For another example, a marking scale may be placed on the surface of the carrying mechanism 920, and some marking points may be set on the marking scale as reference marks. The reference marks may be “cross” marks etched on the marking scale, or other marks of any other shapes. The marking scale may be translucent. The surface of the marking scale may be coated with a reflective film, and the coated marking scale may better reflect the light emitted by the optical engine. Alternatively, the marking scale after the coating may be a translucent marking scale capable of being semi-transparent and semi-reflective to the optical signal. The marking scale may be placed in a non-exposed area, for example, at the edge of the substrate. For another example, if there is already an exposure pattern on the substrate 910, the position of the optical engine may be determined using the exposure pattern on the substrate 910 as a reference mark.

Alternatively, the imaging device may include, for example, a charge coupled device (CCD) or a CMOS imaging device.

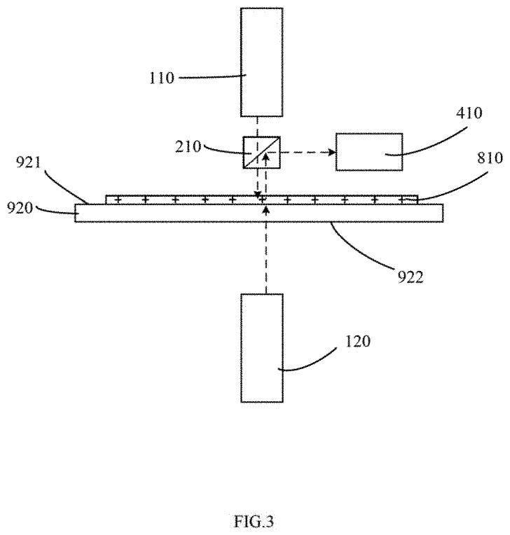

The calibration system 610 provided in the embodiment of the present disclosure is described in detail with reference to FIG. 3.

The calibration system may include a first imaging device 410 operable to receive a first light beam passing through the first optical engine 110 and a second light beam passing through the second optical engine 120 for obtaining the relative position of the first beam and the second beam. The first imaging device may include, for example, an imaging device such as a camera, a video camera. In some embodiments, the first imaging device 410 may also include an image lens that is capable of better focusing the received light beams onto the imaging interface. The first imaging device 410 may thus capture the light beams passing through the first optical engine 110 and the second optical engine 120.

The first imaging device 410 may transmit the relative position of the first beam and the second beam to a control system. The control system generates a first exposure pattern of the first optical engine 110 and a second exposure pattern of the second optical engine 120 based on the relative position of the first beam and the second beam. The first exposure pattern and the second exposure pattern are precisely aligned on the upper and lower surfaces of the substrate. It may be understood that the alignment may include full alignment and may also include minor deviations or offsets within a tolerance.

In the technical solution provided by the embodiment of the present application, the positions of the first optical engine and the second optical engine can be clearly calibrated by a set of beam splitting devices and an imaging device, and the cost can be saved.

The above technical solution may be applicable to a scenario where the positional deviation of the first optical engine 110 and the second optical engine 120 is not large, for example, the imaging of the lens center of the first optical engine 110 and the imaging of the lens center of the second optical engine 120 both fall within the field of view of the first imaging device 410. Thus, the first imaging device 410 can simultaneously receive the light emitted by the first optical engine and the light emitted by the second optical engine for aligning the exposure pattern.

Alternatively, the first imaging device 410 may be provided between the first optical engine 110 and the second optical engine 120 to receive the light beams passing through the first optical engine 110 and the second optical engine 120 in order to align the exposure patterns before the optical engines expose the substrate.

The calibration system may further include a first beam splitting device 210 operable to split the first beam passing through the first optical engine 110 and the second beam of the second optical engine 120. The first imaging device 410 may be configured to receive the first beam and the second beam split by the first beam splitting device 210 to determine a relative position of the first beam and the second beam.

Alternatively, the first beam splitting device 210 and the first imaging device 410 are located on the same side of the substrate.

In the example as shown in FIG. 3, the first beam splitting device 210 and the first imaging device 410 are located on the same side as the first optical engine 110. The first beam splitting device 210 may be located between the first optical engine 110 and the substrate (or carrying mechanism 920). The carrying mechanism 920 is configured to carry a substrate. In some embodiments, the carrying mechanism 920 can also drive the substrate to move relative to the optical engine so as to expose the entire surface of the substrate by the optical engine.

It will be appreciated that during calibration of the optical engines prior to exposing the substrate, the substrate may have not been placed on the carrying mechanism 920, or the substrate may have been placed on the carrying mechanism 920. The embodiments of the present disclosure are not particularly limited.

Alternatively, the carrying mechanism 920 may be transparent or may be hollowed out in the exposure area so that the exposure beam passing through the second optical engine 120 can reach the second side 912 of the substrate 910 for exposing the second side of the substrate 910.

The first beam splitting device 210 may be a beam splitter, for example, the reflectance and the transmittance of the beam splitter are 50% and 50%, respectively. Or, the first beam splitter 210 may be a beam splitter with little reflection or almost total transmission of the exposure beam. The first beam splitting device 210 can also be understood as a prism. For the first optical engine 110, the first light beam passing through the first exposure engine 110 passes through the first beam splitting device 210, reaches the carrying mechanism 920, and returns to the first beam splitting device 210 after being reflected by the carrying mechanism 920. The first beam splitting device 210 may reflect the first beam to the first imaging device 410. For the second optical engine 120, the second light beam passing through the second optical engine 120 may pass through the carrying mechanism 920 to the first beam splitting device 210, which may reflect the second light beam to the first imaging device 410. Thus, the first imaging device 410 can obtain the positions of the first light beam and the second light beam, thereby obtaining the relative positions of the centers of the first optical engine 110 and the second optical engine 120.

Of course, the first beam splitting device 210 and the first imaging device 410 may also be located on the same side as the second optical engine 120. The manner for acquiring the positions of the first optical engine 110 and the second optical engine 120 is similar to the process described above, and will not be repeated here.

Alternatively, the marking scale 810 may also be placed on the carrying mechanism 920, in this case, the process by which the calibration system acquires the first optical engine 110 and the second optical engine 120 may be as follows: a semi-transparent marking scale 810 with markings is placed on the carrying mechanism 920, the semi-transparent marking scale may perform semi-transmission semi-reflection of an optical signal. The markings on the marking scale 810 may be presented in the field of view of the first imaging device 410 and the second imaging device 420, both of which may acquire the markings on the marking scale 810. The optical axes of the first optical engine 110 and the second optical engine 120 are adjusted such that the optical axes of the first optical engine 110 and the optical axes of the second optical engine 120 are perpendicular to the carrying mechanism 920 in the middle. The first light beam passing through the first optical engine reaches the marking scale 810, and is reflected by the marking scale 810, and then returns to the first beam splitting device 210. The first beam splitting device 210 may reflect the first beam into the first imaging device 410. The second light beam passing through the second optical engine 120 may pass through the carrying mechanism 920 and the marking scale 810 to reach the first beam splitting device 210, and the first beam splitting device 210 may reflect the second light beam into the first imaging device 410. Thus, the first imaging device 410 can acquire the first light beam passing through the first optical engine 110, and can determine the position of the first light beam in the marking scale 810. The first imaging device 410 may also acquire a second light beam passing through the second optical engine 120 and be capable of determining the position of the second light beam in the marking scale 810. Since the first light beam and the second light beam use the same reference object as the position reference marking, the first imaging device 410 can acquire the positions of the first optical engine 110 and the second optical engine 120 with respect to the same marking. Thus, after the first imaging device 410 transmits the position information of the first optical engine 110 and the second optical engine 120 with respect to the same marking to the control system, the control system can generate the first exposure pattern and the second exposure pattern from the two position information such that the generated first exposure pattern and the second exposure pattern are aligned on the front and back sides of the substrate 910.

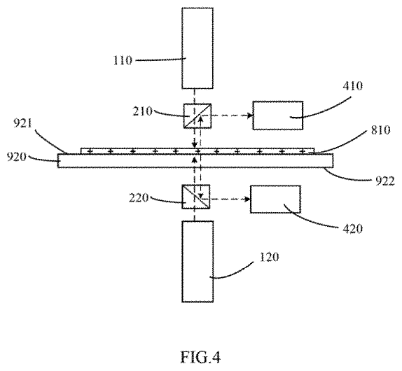

In another implementation, as shown in FIG. 4, the calibration system may further include a second beam splitting device 220 and a second imaging device 420. The second beam splitting device 220 and the second imaging device 420 may be located on the same side as the second optical engine 120. The second light beam passing through the second optical engine 120 passes through the second beam splitting device 220, reaches the marking scale 810, and returns to the second beam splitting device 220 after being reflected by the marking scale 810. The second beam splitting device 220 may reflect the second beam to the second imaging device 420.

It can be understood that the marking scale 810 shown in FIG. 4 can be a semi-transparent and semi-reflective marking scale, or a marking scale that almost completely reflects the optical signal.

In this case, the process of the calibration system acquiring the first optical engine 110 and the second optical engine 120 may be as follows: the marking scale 810 with markings are placed on the carrying mechanism 920, the markings may be presented in the field of view of the first imaging device 410 and the second imaging device 420, both of which may acquire the markings on the marking scale 810. The optical axes of the first optical engine 110 and the second optical engine 120 are adjusted such that the optical axes of the first optical engine 110 and the optical axes of the second optical engine 120 are perpendicular to the carrying mechanism 920 in the middle. The first imaging device 410 can acquire the first light beam passing through the first optical engine 110 and can determine the position of the first light beam in the marking scale 810. The second imaging device 420 may acquire the second light beam passing through the second optical engine 120, and may be capable of determining the position of the second light beam in the marking scale 810. Since the information of the marking scale acquired by the first imaging device 410 and the second imaging device 420 is the same, namely, the first light beam and the second light beam use the same reference object as the position reference marking, the first imaging device 410 and the second imaging device 420 are capable of acquiring the positions of the first optical engine 110 and the second optical engine 120 relative to the same markings. Therefore, after the first imaging device 410 and the second imaging device 420 transmit the position information of the first optical engine 110 and the second optical engine 120 with respect to the same marking to the control system, the control system can generate the first exposure pattern and the second exposure pattern from the two position information such that the generated first exposure pattern and the second exposure pattern are aligned on the front and back sides of the substrate 910.

In the technical solution shown in FIG. 4, since both upper and lower surfaces of the substrate are provided with calibration systems, that is, a set of beam splitting devices and imaging devices are respectively provided on the upper and lower surfaces of the substrate, therefore, the first imaging device is capable of acquiring the optical signal emitted by the first optical engine regardless of the positional deviation of the first optical engine and the second optical engine. The second imaging device can also acquire the optical signal emitted by the second optical engine, and thus can align the exposure pattern. Therefore, the scheme shown in FIG. 4 does not have any limitation on the positional deviation between the first optical engine and the second optical engine, and can be applied to a scene where the positional deviation between the first optical engine and the second optical engine is arbitrary.

Embodiments of the present application also provide a digital double-sided lithography or exposure system that can be used to clearly calibrate the spatial position of the optical engine before exposing the substrate.

As shown in FIG. 2, the digital double-sided lithography or exposure system includes a first optical engine 110 for exposing a front surface of a substrate 910 and a second optical engine 120 for exposing the back surface of the substrate 910.

The digital double-sided lithography or exposure system may also include a calibration system 610 that may be used to calibrate position information of the first optical engine 110 and the second optical engine 120.

The digital double-sided lithography or exposure system further includes a control system 710 for generating a first exposure pattern and a second exposure pattern based on the position information of the first optical engine 110 and the second optical engine 120. The first exposure pattern and the second exposure pattern are aligned on the front and back surfaces of the substrate 910.

In the digital double-sided lithography or exposure system provided by the embodiments of the present disclosure, a calibration system can be used to clearly calibrate the position of the optical engines. In such a way, the control system may generate a first exposure pattern and a second exposure pattern such that the first exposure pattern and the second exposure pattern compensate for the positional offset of the first optical engine and the second optical engine. The exposure patterns are precisely aligned on the front and back sides of the substrate, so that the accurate exposure on the front and back sides of the substrate can be realize in the exposure process of the substrate.

The calibration system 610 can also be used to re-calibrate the position of the optical engine after the relative positions of the first optical engine 110 and the second optical engine 120 are changed in the subsequent use. Accurate exposure of the substrate 910 is thus achieved.

Alternatively, the manner in which the calibration system 610 obtains the position information of the first optical engine 110 and the second optical engine 120 may refer to the above description, and the description thereof is omitted to avoid repetition.

In the technical solution provided by the embodiment of the present disclosure, generally, the structures and functions of the first optical engine 110 and the second optical engine 120 on the upper and lower sides of the substrate 910 are completely the same. Hence, the relative position of the exposure pattern generate by the optical engine can be adjusted in accordance with the relative position between the optical centers of the optical engine to compensate for the offset between the two optical engines, such that the exposure patterns of the two optical engines are precisely aligned on both sides of the substrate. Thus, the exposure quality of the exposure system can be remarkably improved on the basis of the improvement in productivity and yield.

Alternatively, in a subsequent exposure process, the digital double-sided lithography or exposure system may each generate an exposure pattern according to the previously acquired position information. Alternatively, the digital double-sided lithography or exposure system may acquire the position information of the two optical engines in real time, and adjust the exposure patterns generated by the two optical engines in real time.

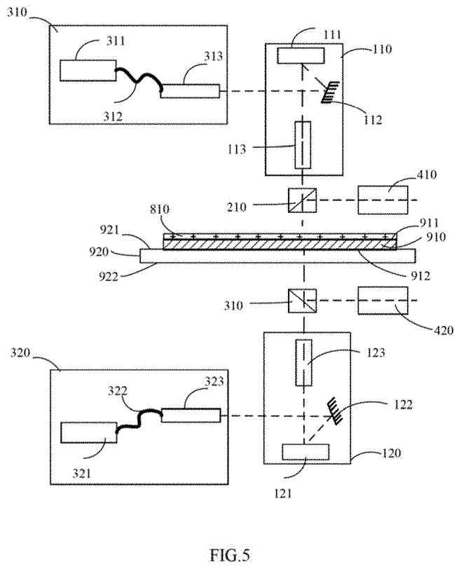

As shown in FIG. 5, the digital double-sided lithography or exposure system may further include a first light source system 310 for providing exposure beams to the first optical engine 110. The first light source system 310 may include an exposure light source 311. The exposure light source 311 may, for example, provide ultraviolet rays (UV) to expose the substrate 910 coated with a photosensitive material such as photo-resist. The first light source system 310 may further include, for example, an optical fiber 312 and a light collimating and homogenizing device 313. The exposure light beam emitted by the exposure light source 311 enters the collimating and homogenizing device 313 through the optical fiber 312 to collimate and/or homogenize the exposure beams. It should be understood that the first light source system 310 may include only the exposure light source 311, or may include an exposure light source whose output light beams have been collimated and/or homogenized. The embodiment of the present application is not limited thereto. Similarly, the second light source system 320 for providing the exposure beams to the second optical engine 120 may include an exposure light source 321, an optical fiber 322, and a light collimating and homogenizing device 323.

Alternatively, the first optical engine 110 may include a spatial light modulator 111 for generating the first exposure pattern, a reflection mirror 112 for changing the transmission direction of the light beam, and a projection system 113 for projecting the first exposure pattern onto the first surface 911 of the substrate 910. Similarly, the second optical engine 120 may include a spatial light modulator 121 for generating the second exposure pattern, a reflection mirror 122 for changing the transmission direction of the light beam, and a projection system 123 for projecting the second exposure pattern onto the second surface 912 of the substrate 910.

The light emitted from the exposure light sources 310 and 320 is reflected by the reflection mirrors 112 and 122, and then received by the spatial light modulators 111 and 121. The spatial light modulators 111, 121 may generate a desired pixel pattern or pixel mask pattern that may persist for a specific time synchronized with the movement of the carrying mechanism 920. The light generated by the pixel mask pattern of the spatial light modulators 111, 121 is input to the projection systems 113, 123. Lights passing through the projection system 113 are focused onto the first side 911 of the substrate 910 to expose the first side 911 of the substrate 910. Lights passing through the projection system 123 pass through the carrying mechanism 920 and are focused onto the second side 912 of the substrate 910 to expose the second side 912 of the substrate 910. Thus, the pixel mask pattern is projected onto both sides of the substrate 910.

Alternatively, the first light beam and the second light beam in the calibration process described above may also be exposure light beams, which may carry information of the exposure pattern.

In the system shown in FIG. 4, a marking scale 810 may be placed on a non-exposed area of the substrate that does not affect the exposure of the substrate by the optical engine during exposure. In addition, during the exposure process, the calibration system can also calibrate the spatial positions of the two optical engines in real time through the marking scale 810 to align the exposure patterns in real time, so that the substrate can be exposed more accurately.

The beam splitting device shown in FIG. 4 is disposed between the optical engine and the substrate, but the embodiment of the present application is not limited thereto. For example, the first beam splitting device 210 may also be disposed within the first optical engine 110. In particular, the first beam splitting device 210 may be disposed between the spatial light modulator 111 of the first optical engine 110 and the projection system 113.

Similarly, the second beam splitting device 310 may also be disposed within the second optical engine 120. Specifically, the second beam splitting device 310 may be disposed between the spatial light modulator 121 of the second optical engine 120 and the projection system 123.

The digital double-sided lithography or exposure system may also include a carrying mechanism 920 capable of moving the substrate 910 relative to the first optical engine 110 and the second optical engine 120. The carrying mechanism 920 may include an XY moving stage and a Z-axis control stage. The XY moving stage may realize relative movement of the optical engine in the plane where the substrate is located. The Z-axis control stage can control the optical engine to move in a direction perpendicular to the plane of the substrate 910 to change the relative distance or height from the substrate 910 so that a beam passing through the optical engine can be focused onto the substrate 910. The two sides 921 and 922 of the carrying mechanism 920 may be transparent in the exposure area or may be hollowed out so that the exposure beams passing through the second optical engine 120 can reach the second side 912 of the substrate 910 for exposing the second side of the substrate 910.

The two sides 911 and 912 of the substrate 910 may include an etch layer or coating layer sensitive to the exposure beams. The substrate may be a PCB board or wafer for manufacturing a PCB, a sheet board for a lead frame, or various other flat plates for liquid crystal display manufacturing, document printing, photocopying, and the like.

In the exposure process, an exposure light beam carrying the pattern information is irradiated on a substrate sensitive to the exposure light beam, and the pattern information can be etched on the substrate, so as to realize the exposure of the substrate.

The calibration process before exposure will be described with reference to FIG. 5.

During the pre-exposure calibration, the optical axes of the first optical engine 110 and the second optical engine 120 may have been pre-aligned in design and manufacture. The pre-alignment may be understood as a coarse alignment. The optical axes of the first optical engine 110 and the second optical engine 120 are perpendicular to the plane of the substrate 910. In the embodiment of the present application, the marking scale 810 can be placed on the carry mechanism 920 as a reference mark. When the exposure light sources 311, 321 are turned on, and the exposure light sources 311, 321 generate appropriate light intensity, and then the Z-axis positions of the first optical engine 110 and the second optical engine 120 are adjusted, lights passing through the first optical engine 110 and the second optical engine 120 are focused onto the surface 921 of the carrying mechanism 920.

A part of the light beams passing through the first optical engine 110 is transmitted through the first beam splitting device 210, irradiated onto the marking scale 810, carried information of the reference mark, and reflected at the surface of the marking scale 810. The reflected lights (i.e., the first light beams) are reflected by the first beam splitting device 210 into the first imaging device 410 and the position of the optical center of the first light beam relative to the reference marking is acquired by the camera of the first imaging device 410, thereby obtaining the position of the optical axis of the first optical engine 110.

A part of the light beam passing through the second optical engine 120 is transmitted through the second beam splitting device 310, irradiated onto the marking scale 810, carried the information of the reference mark, and reflected at the surface of the marking scale 810. The reflected lights (i.e., the second beams) are reflected by the second beam splitting device 220 into the second imaging device 420 and the position of the optical center of the second beam relative to the reference mark is acquired by the camera of the second imaging device 420, thereby obtaining the position of the optical axis of the second optical engine 120.

The position information of the optical axis of the first optical engine 110 and the position information of the optical axis of the second optical engine 120 may be stored in a computer control system for pattern alignment during exposure. For example, the control system may control the relative positions of the exposure pattern generated by the first optical engine 110 and the exposure pattern generated by the second optical engine 120 to compensate for the offset of the optical axes of the first optical engine 110 and the second optical engine 120, such that the pattern projected onto the substrate 910 by the first optical engine 110 and the pattern projected onto the substrate 910 by the second optical engine 120 are accurately aligned.

In the embodiment of the present disclosure, the execution of the calibration process and the exposure process are not particularly limited.

As an example, since the marking scale is not placed on the exposure area of the substrate, the calibration process and the exposure process may be operated at the same time. For example, the calibration system calibrates the position of the optical engine prior to each exposure, and the control system can then disassemble and align the exposure pattern based on the position adjustment of the optical engine. The optical engine may then expose the substrate with the aligned exposure pattern. This ensures that the exposure pattern generated by the optical engine is precisely aligned each time.

As a further example, since the position of the optical engine does not change substantially after installation. Therefore, the position of the optical engine can be calibrated only once, and the subsequent exposure process does not need to calibrate the position of the optical engine. The exposure pattern is directly generated according to the previously calibrated position information. The substrate is exposed. This exposure method is simple to operate, easy to be implemented, and can improve the exposure speed.

However, there are some special cases, such as temperature changes, or after the optical engine has been used for a long period of time, the position of the optical engine may change. In this case, in order to ensure the exposure accuracy, the position of the optical engine may be re-calibrated before exposure, and subsequently the substrate may be exposed by using the re-calibrated position information to generate an exposure pattern.

The exposure light sources 311, 321 may provide energy radiation including at least one of ultraviolet light, infrared light, visible light, electron beam, ion beam, and X-ray.

Of course, in the calibration process, the exposure pattern may also be used for calibration. For example, an exposure pattern may be sent to the spatial light modulators 111, 121, and the light emitted from the exposure light sources may be projected onto the substrate 910 after passing through the spatial light modulators. The Z-axis position of the optical engine can then be adjusted so that the exposure pattern can be focused onto the surface of the carrying mechanism 920. The first imaging device 410 and the second imaging device 420 can acquire the relative positions of the exposure pattern and the reference markings to calibrate the positions of the first optical engine and the second optical engine to align the exposure pattern.

During the exposure of the substrate 910 after the alignment, the absolute positions of the first optical engine 110 and the second optical engine 120 may be controlled to remain unchanged, so as to ensure accurate exposure of the upper and lower exposure patterns. For example, in the exposure process, the entire substrate can be exposed by the optical engine by controlling the substrate 910 on the carrying mechanism 920 to move in the XY direction.

In addition, the relative positions of the first optical engine 110 and the second optical engine 120 can be kept unchanged to ensure accurate exposure of the exposure patterns of the front and back sides of the substrate 910. For example, during the exposure, a set of control mechanisms may be used to control the first optical engine 110 and the second optical engine 120 to move simultaneously such that the relative positions of the first optical engine 110 and the second optical engine 120 remain unchanged, this would ensure that the exposure patterns projected onto the substrate 910 by the first exposure engine 110 and the second exposure engine 120 are always maintained in alignment.

Optionally, the first imaging device and the second imaging device may further include an image lens to better focus the first beam and the second beam onto the imaging interface.

In the embodiment of the present disclosure, the arrangements of the optical engines are not limited.

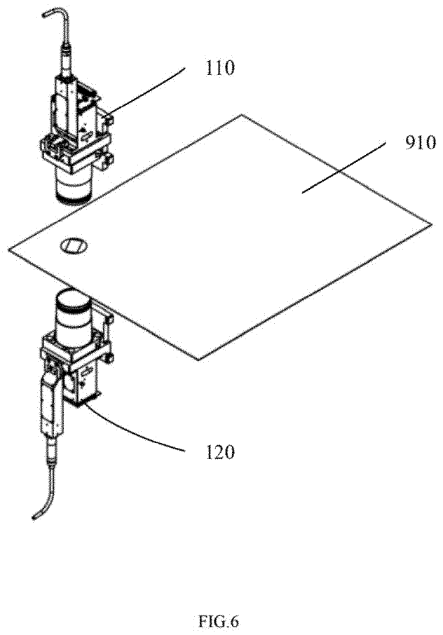

For example, as shown in FIG. 6, one optical engine may be provided on each of the front and back sides of the exposure substrate. The first optical engine 110 disposed on the front surface is used to expose the front surface of the substrate 910, and the second optical engine 120 disposed on the back surface is used to expose the back surface of the substrate 910.

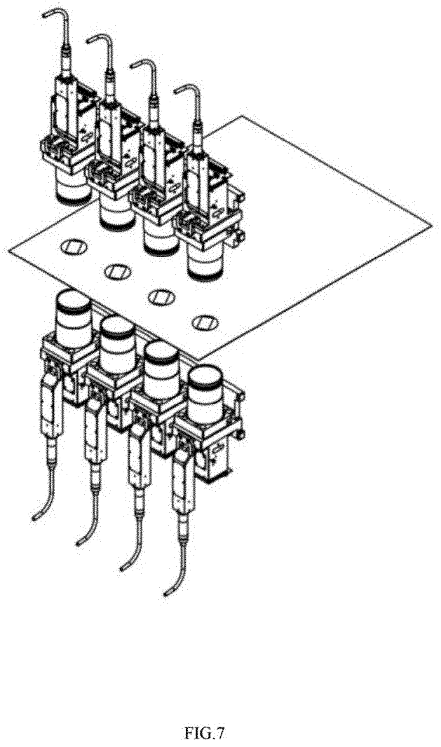

For another example, a number of optical engines are arranged on each of the front and back surfaces of the exposure substrate, and 2˜N optical engines may be arranged on one side of the substrate. The N is a natural number and N≥2. As shown in FIG. 7, a row of optical engines can be arranged on both sides of the substrate, and the exposure rate can be improved by arranging one row of optical engines on one side of the substrate. The exposure rate can be reduced by 1/N compared to a scheme in which only one optical engine is provided.

In this case, the setting direction of the marking scale may be set along the alignment direction of the optical engine. For example, the length direction of the marking scale is parallel to the alignment direction of the optical engine. Of course, the longitudinal direction of the marking scale may be any other direction.

For another example, a number of rows of optical engines may be arranged on each of the front and back sides of the exposure substrate, for example, the optical engines on each side of the exposure substrate may be arranged in an array of M*N, where M and N are integers greater than or equal to 2. The exposure rate of the optical engine can be further improved by setting multiple rows of the optical engine.

In this case, the setting direction of the marking scale may be set along the alignment direction of the optical engine, or perpendicular to the alignment direction of the optical engine, or in an arbitrary angle direction.

It should be noted that, according to the above description, the physical locations of the first optical engine and the second optical engine may not be perfectly aligned, and thus, the positions of the number of engines on the upper surface and the number of engines on the lower surface of the substrate shown in FIG. 5 and FIG. 6 may also not be perfectly aligned, allowing a certain offset. The offset in the position of the optical engines may be compensated for by adjusting the relative position of the exposure patterns. The pattern projected onto the substrate by the optical engine of the upper surface of the substrate is aligned with the pattern projected onto the substrate by the corresponding optical engine of the lower surface.

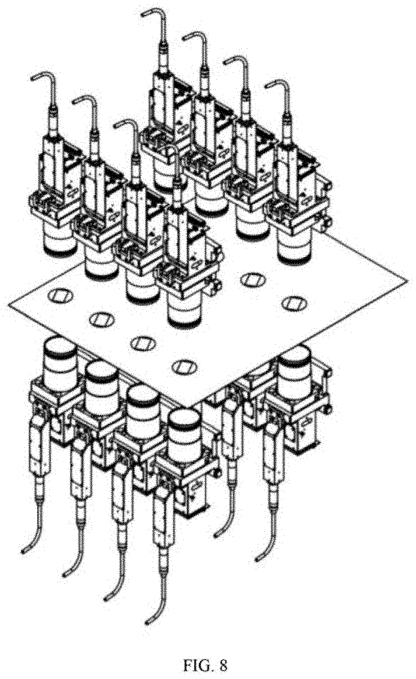

Alternatively, for a structure having multiple rows of optical engines, the optical engines of two adjacent rows may be staggered between them. As shown in FIG. 8, there is a certain misalignment between the first row of optical engines and the second row of optical engines, so that the exposure of the entire substrate can be completed by a single scan. In other words, in the process of exposing the substrate, the exposure of the entire substrate can be completed only by moving along one direction of the plane of the substrate, which can greatly improve the exposure speed and simplify the exposure process. In particular for a super-large substrate, the exposure time can be greatly shorten by adopting a multi-row optical engine for exposure.

Alternatively, the optical engine may adopt a technique of oblique scanning to expose the substrate during scanning exposure. In general, the exposure area of a maskless optical engine is a rectangular area. The oblique scanning technique is defined that the rectangle is inclined with respect to the scanning direction. The angle of the inclination may be 1 to 10 degrees.

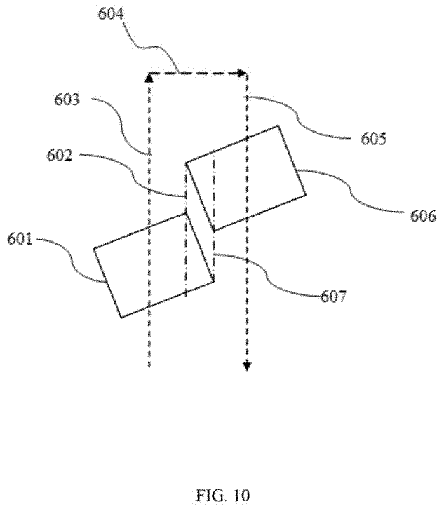

As shown in FIG. 10, the scanning path of the optical engine may be first scanning along a direction 603, then scanning along a direction 604 perpendicular to the direction 603, and then scanning along a direction 605. The exposure region 601 and the exposure region 606 are inclined, and they are arranged in the scanning directions 603 and 605 such that the sum of the widths of the exposure regions in the directions perpendicular to the scanning directions 603 and 605 is constant. There is a stitch area 602, 607 between the two scanning directions 603 and 605. Since the exposure regions 601, 606 are inclined and the stitch area between the lines 602, 607 are smooth transitions between two scans, multiple scan exposures can result in a large exposure area. The exposure over the entire substrate is accurate and even, by using a compact maskless optical engine, a small exposure area can be obtained. In addition, due to the compact structure of each maskless optical engine, the use of oblique scan technology can reduce aberration, improve the resolution of the exposure pattern and ensure excellent imaging effect.

Of course, in order to increase the exposure speed, one or more rows of the above-described optical engines may also be used for the exposure. Further, the multi-row optical engine may be arranged in a staggered manner.

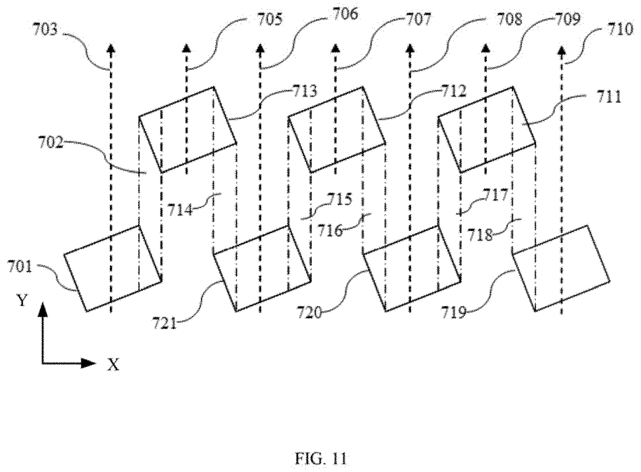

FIG. 11 is a schematic diagram of stitching areas formed after one exposure of the two rows of optical engines using the oblique scanning technique according to an embodiment of the present application.

In the example shown in FIG. 11, two rows of optical engines are staggered, and the exposure of the entire substrate needs only one scanning, that is, only one scanning along the Y direction, to complete the exposure of the entire substrate. The exposure regions 701, 721, 720, and 719 are the first row, and the exposure regions 713, 712, and 711 are the second row. The first row scans along paths 703, 705, 708, 710 and the second row scans along paths 705, 707, 709. The stitch areas are 702, 714, 715, 716, 717, 718. Since the pitch of the optical engines is the same as the effective scanning width of each optical engine, the staggered arrangement of the optical engines requires only a single scan exposure, eliminating the need for an X stage.

The oblique scanning technology can not only improve the lithography precision, but also increase the exposure area.

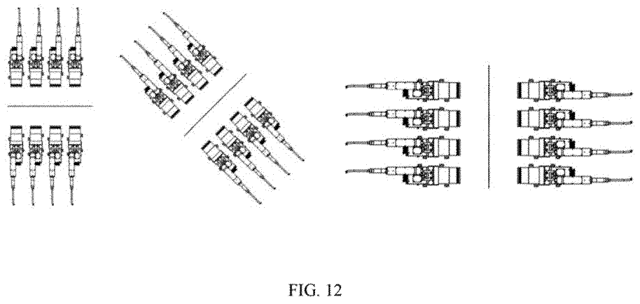

Alternatively, the placement position of the exposure substrate is not particularly limited in the embodiments of the present disclosure. As shown in FIG. 12, the exposure substrate may be placed horizontally, may be placed vertically, or may be placed obliquely with any angle. In the exposure process, as long as the optical axis of the optical engine is perpendicular to the exposure substrate, accurate exposure can be performed on the exposure substrate. Similarly, since the exposure substrate needs to be placed on the carrying mechanism for exposure, the position of the carrying mechanism can also be placed horizontally, vertically or at an arbitrary angle of inclination.

Alternatively, the substrate may be fixed by a carrying mechanism so that the first optical engine and the second optical engine can better expose the front and back surfaces of the substrate. In that embodiment of the present disclosure, the layouts of the carry mechanism are not particularly limited. The carrying mechanism may be understood as a mechanism for carrying or fixing a substrate.

As one example, the carrying mechanism may be a mechanism using two pieces of glass plates to secure the substrate. For example, an exposure substrate may be placed between the two glass plates, and then a middle region of the two glass plates is evacuated, and the exposed substrate may be flattened using the two glass plates. In the exposure process, the optical axis of the exposure engine is perpendicular to the plane of the glass plates so as to realize the exposure of the substrate.

Wherein, the glass plate can be transparent, and the glass plate is insensitive to the exposure light source. The exposure light beam can pass through the glass plate to reach the surface of the substrate, so that the front and back surfaces of the substrate can be exposed.

As another example, the substrate may be secured by means of a glass plate and a clamping mechanism. For example, one side of the glass plate is provided with a clamping mechanism with a fixing base and the other side is provided with a clamping mechanism with movable base. The substrate may be placed on the glass plate and then secured to the glass plate by the fixed clamping mechanism and the movable clamping mechanism. The carrying to mechanism can be compatible with exposure substrates of different sizes, and the position of the movable base can be flexibly adjusted according to the actual width of the substrate.

After the substrate is placed on the glass plate, one side of the substrate may be fixed to the glass plate by a fixed base and the other side may be fixed by a movable base which may cause the substrate to be flattened on the glass plate. In the exposure process, the projection direction of the optical lens of the optical engine is perpendicular to the exposure substrate so as to realize the exposure of the substrate.

Of course, two fixed clamping mechanisms may be used to fix the substrate. In this way, the substrate having a specific size can be fixed.

Since the glass plate is transparent and insensitive to the exposure light source, the exposure light source emitted by the optical engine can reach one surface of the substrate through the glass plate to expose the surface. For the other surface of the substrate, since the clamping mechanism is located at the edge of the substrate, such as in the non-exposed area, the exposure of the substrate to the optical engine is also not affected. Therefore, the carrying mechanism can realize double-sided exposure of the substrate by the optical engine.

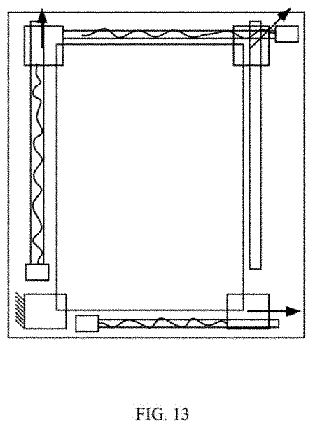

As yet another example, the fixation of the substrate may be achieved by using a clamping mechanism. As shown in FIG. 13, four clamping mechanisms may be used, each of which clamps one corner of the exposed substrate and pulls the substrate flat by using pulling forces from different directions.

Alternatively, the four clamping mechanisms may all be moveable, and the four clamping mechanisms may be used to flat the substrate in a diagonal outward direction. Or one of the four clamping mechanisms may be a fixed clamping mechanism and the remaining three may be a movable clamping mechanism. In the flattening process, the pulling directions of the three substrates may be the direction as shown in FIG. 13, or other directions as long as the substrate can be flattened.

Likewise, during exposure, the projection direction of the optical lens of the optical engines may be perpendicular to the substrate to realize exposure to the substrate.

Of course, the four clamping mechanisms can also be located at other positions of the substrate as long as the substrate can be pulled flat in different directions.

Since the four clamping mechanisms are all located at edge positions of the substrate, for example, at the four corners of the substrate, double-sided exposure of the substrate by the optical engine can be achieved.

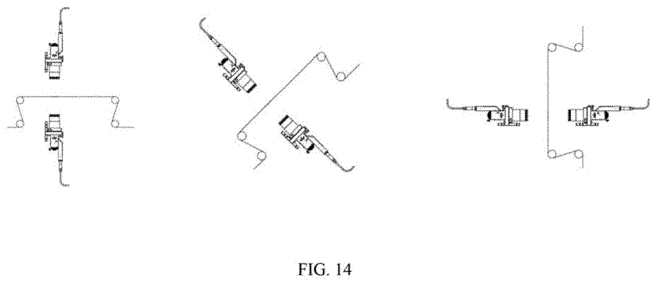

As a further example, in the case where the exposure substrate is a full-roll flexible plate, the substrate may be flattened using a roller or roller wheel as shown in FIG. 14. For example, the substrate may be rolled in from one side of the roller and rolled out from the other side, and the middle exposure area may be flattened by the roller.

Since the middle exposure region can be irradiated by the optical engine, both sides of the substrate can be exposed by the optical engine.

In the embodiment of the present disclosure, the position of the roller wheel is not particularly limited. As shown in FIG. 14, the roller wheel may flat the substrate in a horizontal direction, may be vertical, or may be inclined at an arbitrary angle as long as the optical axis of the optical engine is perpendicular to the substrate.

Alternatively, the method for scanning the substrate by the optical engine is not particularly limited in the embodiments of the present disclosure. As long as the optical engine and the substrate are capable of a relative movement and a complete exposure of the surface of the substrate can be achieved.

A specific scanning method may be as shown in table 1.

TABLE 1

| | | The moving direction |
|---|---|---|
| | | of the base plate |
| | Direction of movement of the | driven by the carrying |
| Number | optical engine | mechanism |
| 1 | Move in Z direction, not move | Move in X, Y |
| | in X and Y directions | directions |
| 2 | Move in X, Y and Z directions | not move in X and Y |
| | | directions |
| 3 | Move in X and Z directions | Move in Y direction |
| 4 | Move in Y and Z directions | Move in X direction |

For the above four cases, the optical engine can be moved in the Z direction, which can be the direction perpendicular to the substrate or the carrying mechanism, and the optical engine can focus the exposure pattern on the substrate by adjusting the position of the Z axis, realizing the exposure of the substrate.

In that first case, in the process of exposing the substrate, the optical engine is kept stationary in the X and Y direction, and the substrate is driven to move in the X and Y directions by the carrying mechanism, thereby achieving the exposure of the entire surface of the substrate by the optical engine.

In this case, since that position of the optical engine in the X and Y directions remain unchanged, if the position of the exposure pattern is aligned before the exposure, the optical engine performs a subsequent exposure process. Both sides of the substrate can be precisely exposed according to the position of the exposure pattern after alignment.

In that second case, in the process of exposing the substrate, the substrate remain stationary in the X and Y directions, that is, the position of the substrate remains unchanged, and the optical engine can be controlled to move in the X and Y directions, thereby achieving exposure of the entire surface of the substrate.

In this case, since the positions of the optical engines change during the exposure, for a double-sided lithography system, the optical engines on the front side of the substrate and the optical engine on the back side of the substrate are required to be controlled by the control system to have the same motion trajectory, that is, to control the optical engine on the front side and the back side to move simultaneously. In order to realize that precise exposure of the optical engine to the front and back surface of the substrate.

In a third case, the optical engines can be move in the X direction to realize exposure of the substrate in the X direction by the optical engines, and the substrate can be moved in the Y direction to realize exposure of the substrate in the Y direction by the optical engine, thus, exposure of the entire surface of the substrate by the optical engines can be realized.

In the fourth case, the optical engines may be move in the Y direction to achieve exposure of the substrate in the Y direction by the optical engine, and the substrate may be moved in the X direction to achieve exposure of the substrate in the X direction by the optical engine, thus, exposure of the entire surface of the substrate by the optical engine can be realized.

In the third and fourth case, similar to the second case, since the position of the optical engine change during the exposure process, for a double-sided lithography system, a control system is required to control the simultaneous movement of the optical engine on the front side of the substrate and the optical engine on the back side of the substrate so as to achieve accurate exposure of the optical engine to the front and back surfaces of the substrate.

The above-described scanning method means that one of the optical engines and the substrate can move in the X direction and one of the optical engines and the substrate can move in the Y direction, of course, the embodiments of the present application are not limited thereto. The optical engines and the substrate can also be moved in both the X and Y directions. In the exposure process, the optical engine can move in the positive direction of the X axis, while the substrate can move in the negative direction of the X axis, thereby realizing the exposure of the substrate in the X direction by the optical engine. Likewise, the optical engine can be moved in the positive direction of the Y axis, while the substrate can be moved in the negative direction of the Y axis, thereby realizing the exposure of the substrate in the Y direction by the optical engine. Thus, exposure of the entire surface of the substrate by the optical engine can be realized.

The change in position of the optical engines described above may refer to a change in position of the optical lens in the optical engine. Controlling the movement of the optical engine may refer to controlling the movement of the optical lens in the optical engine.

The embodiments of the present disclosure do not particularly limit the implementation manners of the digital double-sided lithography or exposure system.

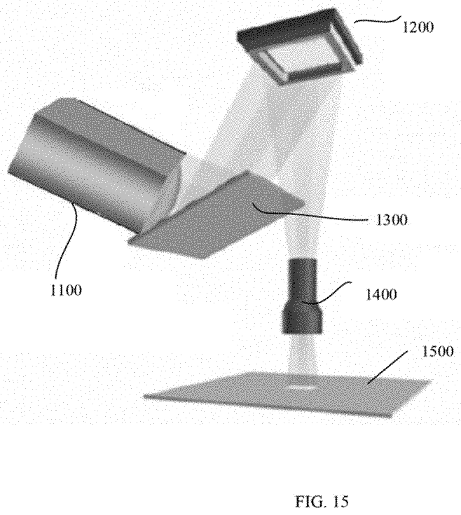

As one example, the digital double-sided lithography or exposure system may be a system based on digital micro mirror device (DMD) laser imaging. As shown in FIG. 15, the system may include a laser light source 1100, an optical engine and a carrying mechanism 1500. The optical engine may include a light source collimation system 1300, a DMD chip 1200, and an optical imaging system 1400. The laser light source may include a high-power laser light source in which a number of low-power lasers are coupled by optical fibers. The DMD chip may include a programmable micro-mirror array. The optical imaging system may include two sets of upper and lower lenses with a micro-lens array inside. The micro-lens array corresponds to the micro-mirror array on the DMD chip 1200. In order to reduce the size of the spot of the micro mirror. In the system, laser beams are collimated and expand and projected onto a spatial light modulator (DMD) at a certain angle, and are modulated into multiple beams by a micro-mirror array, and the multiple beams can be individually controlled by a micro-mirror. The beams can then be focused onto the substrate in the form of a lattice spot. The system can control the on and off of the beams of the micro-mirror array on the DMD chip 1200 according to the pattern of the desired exposure. At the same time, the computer can synchronously control the carrying mechanism with the substrate to perform graphic array scanning to form a desired pattern on the photosensitive material of the substrate 1500. Then the large area exposure pattern can be obtained by stitching the scanned pattern between the optical engines or by the optical engine itself.

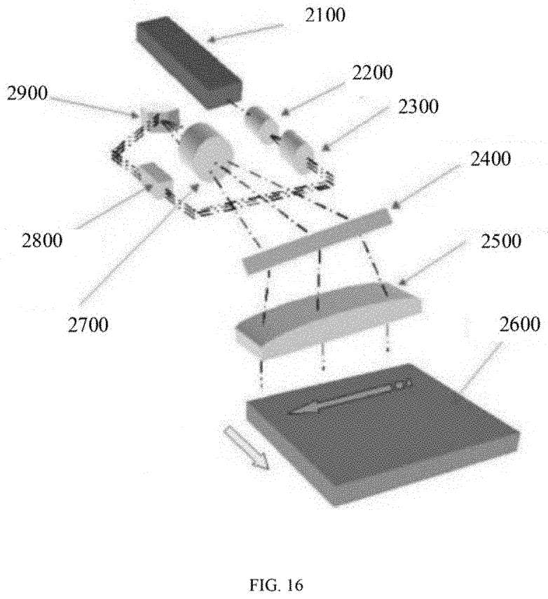

As another example, the digital double-sided lithography or exposure system may be implemented using a single beam of laser scanning. As shown in FIG. 16, the system may include a laser light source 2100, an acousto-optic modulation system (AOM) 2800, a beam shaping system, a rotating mirror system 2400, an F-θ lens system 2700, a moving platform 2600, and the like. The single laser beam emitted by the laser light source enters the acousto-optic modulation system 2800 after the beam shaping, filtering and changing the laser direction by the beam shaping systems 2200 and 2300. The acousto-optic modulation system uses the acousto-optic interaction principle to make the laser beam modulated by the ultrasonic wave to form the on-off switch of the beam. The light beam modulated by the acousto-optic modulation system is reflected by the polygon mirror 2900 and enters the F-θ lens system 2700. This technique utilizes a rotating mirror system 2400, an F-θ lens system 2700, and a condenser lens 2500 to make a uniform scanning of the laser beam perpendicular to the direction of motion of the moving platform 2600. The exposure pattern signal is used to synchronously control the on/off scanning laser beam of the acousto-optic modulation system 2800 and the movement of the machine, so that the sensitivity of the surface of the substrate on the moving platform 2600 at different positions can be realized, and the pattern conversion of the photo-resist can be realized. The system uses a high power singular laser source, which has high exposure power, high precision, large depth of focus, good exposure uniformity and high image quality.

The laser light source can generate UV light at 355 nm.

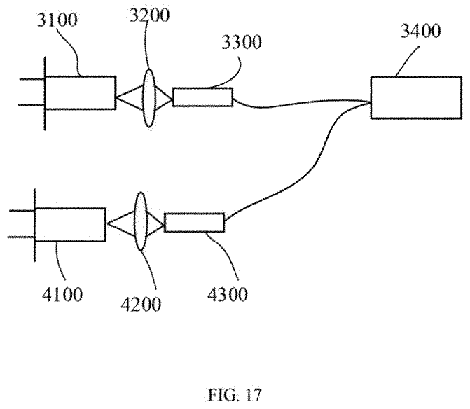

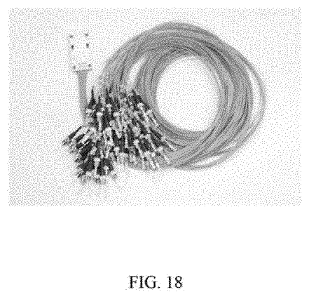

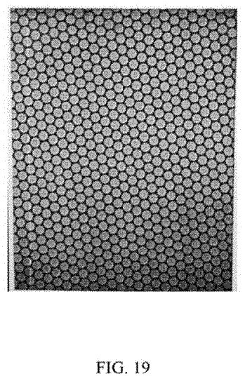

As yet another example, the digital double-sided lithography or exposure system may also be a system based on semiconductor laser fiber coupled close-packed laser lattice imaging. FIG. 18 is a physical diagram of an optical fiber. FIG. 19 is a schematic diagram of a fiber-coupled laser lattice. The main structure of the system may be as shown in FIG. 17. A number of optical fibers may be arranged in a single row or a number of rows of optical fibers by fiber bundle 3400. The optical fiber may be single mode fiber or multimode fiber. Each optical fiber at the other end of the fiber bundle may be provided with an optical fiber connector 3300, 4300 through which a single semiconductor laser may be coupled to a single optical fiber. Then, by controlling the switching of the semiconductor lasers 3100, 4100, a pattern can be output at the light output end of the fiber bundle, and the pattern can be imaged on the substrate surface by the imaging lenses 3200, 4200. The digital double-sided lithography or exposure system of the embodiments of the present disclosure may also implement double-sided exposure of the substrate by using the lithography system.

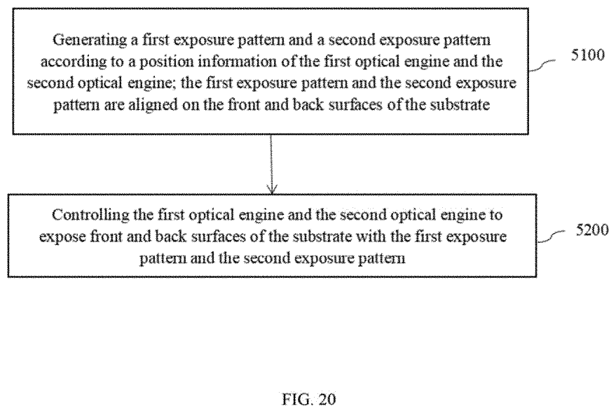

The embodiments of the present disclosure also provide another method for double-sided digital lithography or exposure, which can be applied to the digital double-sided lithography or exposure system provided by the embodiments of the present disclosure described above. FIG. 20 is a schematic flow chart of a method for digitizing lithography or exposure provided in the present disclosure, and as shown in FIG. 20, the method includes:

S5100, generating a first exposure pattern and a second exposure pattern according to a position information of the first optical engine and the second optical engine; the first exposure pattern and the second exposure pattern are aligned on the front and back surfaces of the substrate; and

S5200, controlling the first optical engine and the second optical engine to expose front and back surfaces of the substrate with the first exposure pattern and the second exposure pattern.

In the method for double-sided digital lithography or exposure provided by the embodiment of the present disclosure, the position of the generated exposure pattern can be adjusted according to the positions of the two optical engines to compensate for the offset of the two optical engines. The first exposure pattern projected on the substrate by the first optical engine is precisely aligned with the second exposure pattern projected on the substrate by the second optical engine, so as to realize accurate exposure of both sides of the substrate.

The methods for obtaining the first optical engine and the second optical engine may refer to the above description and are not repeated herein.

Optionally, the method further includes obtaining position information of the first optical engine 110 and the second optical engine 120.

Optionally, the method further includes obtaining position information of reference markings on the substrate 910. The step of generating a first exposure pattern and a second exposure pattern based on the position information according to the first optical engine 110 and the second optical engine 120 includes generating the first exposure pattern and the second exposure pattern based on a positional offset of the first optical engine 110 with respect to the reference marking, and a positional offset of the second optical engine 120 with respect to the reference marking.

Optionally, the step of obtaining the position information of the first optical engine 110 and the second optical engine 120 includes receiving a first light beam passing through the first optical engine 110 and reflected by the first beam splitting device 210, receiving a second light beam passing through the second optical engine 120 and reflected by the second beam splitting device 220, and determining the position of the first light beam and the position of the second light beam as the position of the first optical engine 110 and the position of the second optical engine 120, respectively.

Optionally, the method further includes controlling the positions of the first optical engine 110 and the second optical engine 120 to remain unchanged during the exposure of the substrate 910, or controlling the relative position of the first optical engine 110 and the second optical engine 120 to remain unchanged.

Alternatively, the optical axis of the first optical engine 110 and the optical axis of the second optical engine 120 are both perpendicular to the substrate 910.

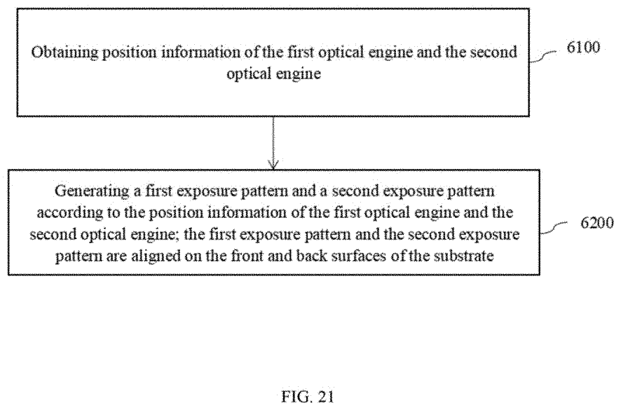

The present disclosure also provides another method of double-sided digital lithography or exposure, which can be applied to the double-sided digital lithography or exposure system provided by the embodiments of the present disclosure described above. FIG. 21 is a schematic flow chart of a method or exposure for digital lithography provided by the present disclosure, and as shown in FIG. 21, the method includes:

S6100: obtaining position information of the first optical engine 110 and the second optical engine 120;

S6200, generating a first exposure pattern and a second exposure pattern according to the position information of the first optical engine 110 and the second optical engine 120; the first exposure pattern and the second exposure pattern are aligned on the front and back surfaces of the substrate 910.

In the digital double-side lithography method provide by the embodiment of the present disclosure, a calibration system is adopted to clearly calibrate the position of two optical engines. In addition, the position of the generated exposure patterns may be adjusted according to the position of the two optical engines to compensate for the offset of the two optical engines. The first exposure pattern projected on the substrate by the first optical engine is precisely aligned with the second exposure pattern projected on the substrate by the second optical engine, so as to realize accurate exposure of both sides of the substrate.

Optionally, the method further includes obtaining position information of a reference marking on the substrate 910. The step of generating a first exposure pattern and a second exposure pattern based on the position information according to the first optical engine 110 and the second optical engine 120 includes generating the first exposure pattern and the second exposure pattern based on a positional offset of the first optical engine 110 with respect to the reference marking, and a positional offset of the second optical engine 120 with respect to the reference marking.

Optionally, the step of obtaining the position information of the first optical engine 110 and the second optical engine 120 includes: receiving a first light beam passing through the first optical engine 110 and reflected by the first beam splitting device 210, receiving a second light beam passing through the second optical engine 110 and reflected by the second beam splitting device 220, and determining the position of the first light beam and the position of the second light beam as the position of the first optical engine 110 and the position of the second optical engine 120, respectively.

Optionally, the method further includes controlling the positions of the first optical engine 110 and the second optical engine 120 to remain unchanged during the exposure of the substrate 910, or controlling the relative position of the first optical engine 110 and the second optical engine 120 to remain unchanged.

Alternatively, the optical axis of the first optical engine 110 and the optical axis of the second optical engine 120 are both perpendicular to the substrate 910.

In that embodiment of the present disclosure, the terms “first,” “second” are only intended to distinguish between different devices, and should not constitute any limitations on the number of devices. The terms “first” and “second” may be interchanged. The embodiments of the present application are not limited thereto.

It should also be understood that the foregoing is merely intended to help those skilled in the art better understand the embodiments of the present disclosure and is not intended to limit the scope of the embodiments of the present application. It will be apparent to those skilled in the art from the examples given above that various equivalent modifications or changes may be made, or certain steps may be newly added, etc. A combination of any two or more of the above embodiments can be made. Such modified, varied, or combined schemes also fall within the scope of the embodiments of the present disclosure.

It should also be understood that the above description of the embodiments of the present application focuses on the differences between the various embodiments that the same or similarities not mentioned may be referred to each other and will not be repeated here for the sake of brevity.

It should also be understood that the sequence numbers of the above-mentioned processes do not mean the order of execution, the order of execution of the processes should be determined by their functions and inherent logic, and should not be construed as any limitation on the implementation of the embodiment of the present application.

Embodiments of the present application also provide a computer-readable medium for storing computer programs. The computer programs include instructions for implementing the above-described method of the digital double-sided lithography of the present disclosure. The readable medium may be a read-only memory (ROM) or a random access memory (RAM), which is not limited by the embodiments of the present disclosure.

Embodiments of the present disclosure also provide a computer program product including instructions for implementing the method of digitizing lithography in any of the embodiments described above.

Those of ordinary skill in the art will appreciate that the example elements and algorithm steps described in connection with the embodiments disclosed herein can be implemented in electronic hardware, or a combination of computer software and electronic hardware. Whether these functions are executed in the manner of hardware or software depends on the specific application and design constraint conditions of the technical solution. One skilled in the art may implement the described functions using different methods for each particular application, but such an implementation should not be considered beyond the scope of the present disclosure.

It will be apparent to those skilled in the art that for convenience and conciseness of description, reference may be made to corresponding procedures in the foregoing method embodiments for the specific operation of the above described systems, devices and units, and is not repeated herein.

In the several embodiments provided herein, it should be understood that the disclosed systems, devices and methods may be implemented in other ways. For example, the above-described embodiment of the device is only illustrative, for example, the division of the units is only a logical function division, and there may be another division manner in actual implementation. For example, multiple units or components may be combined or may be integrated into another system, or some features may be omitted or not performed. On the other hand, the coupling or direct coupling or communication connection shown or discussed with respect to each other may be an indirect coupling or communication connection through interfaces, devices or units, and may be in the form of electrical, mechanical or other forms.

The units described as separate components may or may not be physically separated, the components shown as the units may or may not be physical units, that is, may be located in one place, or may be distributed over a number of network elements. Some or all of the units may be selected according to actual needs to achieve the purpose of the scheme of the present embodiment.

In addition, each functional unit in each embodiment of the present application may be integrated in one processing unit, each unit may be physically present separately, or two or more units may be integrated in one unit.

The functions may be stored in a computer-readable storage medium if it is implemented in the form of software functional units and sold or used as stand-alone products. Based on such understanding, the part of the technical solution of the present application that substantially or makes a contribution to the prior art or the part of the technical solution may be embodied in the form of a software product. The computer software product is stored in a storage medium and includes instructions for causing a computer device (which may be a personal computer, a server, Or a network device or the like) performing all or part of the steps of the method described in various embodiments of the present disclosure. The storage medium includes various media capable of storing program codes, such as a USB disk, a portable hard disk, a read-only memory (ROM), a random access memory (RAM), a magnetic disk or an optical disk.

The above is only a specific embodiment of the present disclosure, but the protection scope of the present disclosure is not limited thereto, and any person familiar with the technical field is within the technical scope disclosed by the present application. Variations or substitutions are readily contemplated and are intended to be included within the scope of protection of the disclosure. Accordingly, the scope of protection of the present disclosure shall be subject to the scope of protection of the claims.

What is claimed is:

1. A double-sided digital lithography or exposure system, comprising:
a first optical engine for exposing a front surface of a substrate;
a second optical engine for exposing a back surface of the substrate;
a control system for generating a first exposure pattern and a second exposure pattern according to a position information of the first optical engine and the second optical engine; the generated first exposure pattern and the generated second exposure pattern are aligned on a front surface and a back surface of the substrate; the control system is further configured to control the first optical engine and the second optical engine to expose the front and back surfaces of the substrate with the first exposure pattern and the second exposure pattern, respectively.

2. The system of claim 1, wherein the system further comprises a calibration system for obtaining the position information of the first optical engine and the second optical engine.

3. The system of claim 2, wherein the calibration system comprises a first imaging device for acquiring the position information of a reference marking on the substrate; the control system is configured to generate the first exposure pattern and the second exposure pattern according to a positional offset of the first optical engine relative to the reference marking and the positional offset of the second optical engine relative to the reference marking.

4. The system of claim 3, wherein the calibration system comprises a first beam splitting device and a second beam splitting device, and the first imaging device and a second imaging device; the first beam splitting device and the first imaging device are provided at one side of the first optical engine; the second beam splitting device and the second imaging device are provided at one side of the second optical engine;
the first imaging device is configured to receive a first light beam passing through the first optical engine and reflected by the first beam splitting device; the second imaging device is configured to receive a second light beam passing through the second optical engine and reflected by the second beam splitting device; and
the control system is further configured to determine a position of the first light beam and a position of the second light beam as the position of the first optical engine and the position of the second optical engine, respectively.

5. The system of claim 1, wherein the control system is further configured to, during an exposure of the substrate, control the position of the first optical engine and the position of the second optical engine to remain unchanged, or control a relative position of the first optical engine and the second optical engine to remain unchanged.

6. The system of claim 1, wherein an optical axis of the first optical engine and an optical axis of the second optical engine 120 are both perpendicular to the substrate.

7. The system of claim 1, wherein the system comprises a first optical engine array and a second optical engine array; the first optical engine array is configured to expose a front surface of the substrate; the second optical engine array is configured to expose a back surface of the substrate; optical engines included in the first optical engine array and the second optical engine array are each arranged in an (M, N) array; the M and N are natural numbers; and the first optical engine array comprises the first optical engine, and the second optical engine array comprises the second optical engine.

8. The system of claim 1, wherein a normal direction of the substrate is a horizontal direction, a vertical direction, or a direction inclined at an arbitrary angle.

9. The system of claim 1, wherein a carrying plate of the substrate comprises two glass plates; and the substrate is provided between the two glass plates and is flattened by the two glass plates.

10. The system of claim 1, wherein a carrying plate of the substrate comprises a glass plate and a clamping plate; the substrate is provided on the glass plate; and the clamping plate is configured to fix the substrate to the glass plate.

11. The system of claim 1, wherein a carrying plate of the substrate comprises four clamping plates; the substrate is fixed by the four clamping plates; the four clamping plates are respectively clamped at different positions of the substrate; and the substrate is flattened by pulling forces in different directions.

12. The system of claim 1, wherein the substrate is a flexible plate; the carrying plate of the substrate is a roller; and the substrate is fixed by a pair of the rollers.

13. The system of claim 1, wherein exposure manners employed in the system comprise any one of a digital micro-mirror DMD based exposure method, a single laser scanning imaging based method, and a semiconductor laser fiber coupled laser based method.

14. A double-sided digital lithography or exposure system, comprising:
a first optical engine for exposing a front surface of the substrate;
a second optical engine for exposing a back surface of the substrate;
a calibration system, configured to obtain a position information of the first optical engine and the second optical engine; and
a control system for generating a first exposure pattern and a second exposure pattern according to the position information of the first optical engine and the second optical engine; the first exposure pattern and the second exposure pattern are aligned on the front and back surfaces of the substrate.

15. A method for double-sided digital lithography or exposure, wherein the method is applied to the digital double-sided lithography or exposure system of claim 1; the method comprises:
generating a first exposure pattern and a second exposure pattern based a position information of the first optical engine and the second optical engine; the generated first exposure pattern and the generated second exposure pattern are aligned on the front and back surfaces of the substrate;
controlling the first optical engine and the second optical engine to expose the front and back surfaces of the substrate with the generated first exposure pattern and the generated second exposure pattern, respectively.

16. The method of claim 15, wherein the method further comprises:
acquiring the position information of the first optical engine and the second optical engine.

17. The method of claim 16, wherein the method further comprises:
acquiring a position information of a reference mark on the substrate; and
the step of generating the first exposure pattern and the second exposure pattern based on the position information of the first optical engine and the second optical engine comprises:
generating the first exposure pattern and the second exposure pattern based on a positional offset of the first optical engine with respect to the reference mark and the positional offset of the second optical engine with respect to the reference mark.

18. The method of claim 17, wherein the step of obtaining the position information of the first optical engine and the second optical engine comprises:
receiving a first light beam passing through the first optical engine and reflected by the first beam splitting device;
receiving a second light beam passing through the second optical engine and reflected by a second beam splitting device;
determining a position of the first light beam and a position of the second light beam as the position of the first optical engine and the position of the second optical engine respectively.

19. The method of claim 15, wherein the method further comprises:
controlling the position of the first optical engine and the position of the second optical engine to remain unchanged during an exposure of the substrate; or controlling a relative position of the first optical engine and the second optical engine to remain unchanged.

20. The method of claim 15, wherein an optical axis of the first optical engine and an optical axis of the second optical engine are both perpendicular to the substrate.

21. A method for double-sided digital lithography or exposure, wherein the method is applied to the digital double-sided lithography or exposure system of claim 14, the method comprises:
acquiring a position information of the first optical engine and the second optical engine;
generating a first exposure pattern and a second exposure pattern according to the position information of the first optical engine and the second optical engine; and the first exposure pattern and the second exposure pattern are aligned on the front and back surfaces of the substrate.
